(19) United States
(12) Patent Application Publication
(10) Pub. No.: US 2020/0021310 A1
(43) Pub. Date: Jan. 16, 2020

(54) INFORMATION PROCESSING METHOD AND APPARATUS, AND DEVICE

(71) Applicant: HUAWEI TECHNOLOGIES CO., LTD., Shenzhen (CN)

(72) Inventors: Chen Zheng, Shanghai (CN); Xiaojian Liu, Shenzhen (CN); Yuejun Wei, Shanghai (CN); Xin Zeng, Shenzhen (CN)

(73) Assignee: HUAWEI TECHNOLOGIES CO., LTD., Shenzhen (CN)

(21) Appl. No.: 16/580,398

(22) Filed: Sep. 24, 2019

Related U.S. Application Data
(63) Continuation of application No. PCT/CN2018/077744, filed on Mar. 1, 2018.

(30) Foreign Application Priority Data
Mar. 24, 2017 (CN) 201710185972.6

(51) Int. Cl. H03M 13/15; H03M 13/11

(52) U.S. Cl. CPC H03M 13/155; H03M 13/1148

(57) ABSTRACT

Embodiments of the present invention disclose an information processing method and apparatus, and a device. The method includes: if Rᵣₑₐₗ is greater than or equal to Rₘᵢₙ, determining, based on a maximum code block length Kₘₐₓ of an LDPC (low-density parity-check code) code, a quantity C of code blocks into which a transport block is to be segmented, where Rᵣₑₐₗ is a largest one among an encoding code rate of the transport block, a code rate limit of the transport block, and a minimum code rate of the LDPC code, and Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

### CROSS-REFERENCE TO RELATED APPLICATIONS

This application is a continuation of International Application No. PCT/CN2018/077744, filed on Mar. 1, 2018, which claims priority to Chinese Patent Application No. 201710185972.6, filed on Mar. 24, 2017. The disclosures of the aforementioned applications are hereby incorporated by reference in their entireties.

### TECHNICAL FIELD

The present invention relates to the field of communications technologies, and in particular, to an information processing method and apparatus, and a device.

### BACKGROUND

In an LTE protocol, a longest bit sequence supported by a turbo encoder during encoding is 6144 bits (bit). To support encoding of a longer bit sequence, a code block segmentation module is concatenated before the turbo encoder. The code block segmentation module is configured to segment a transport block (TB) larger than 6144 bits into a plurality of code blocks (CB) for separate encoding. After turbo decoding, information data of different code blocks is concatenated to restore an original transport block (or referred to as “an information sequence”). FIG. 1 is a schematic diagram of a code block segmentation scenario. If a length B obtained after 24 TB-CRC (Cyclic Redundancy Check) bits are attached to the original transport block is greater than Z=6144 bits, block segmentation needs to be performed. After the block segmentation, CB-CRC bits of L=24 may be further added to each code block. Code block segmentation performed by using a turbo code is limited by a length of a quadratic polynomial permutation (QPP) interleaver. A value of a length of each code block obtained after the segmentation needs to be equal to a value K in a turbo code interleaver parameter table shown in FIG. 2. The encoder may deduce, based on a determined value K, a quantity of code blocks into which the transport block is to be segmented.

A low-density parity-check code (LDPC) not only has good performance close to the Shannon limit, but also has relatively low decoding complexity and a flexible structure, and is a research hotspot in the field of channel encoding in recent years. A quasi-cyclic low-density parity-check code (QC-LDPC) is used as an example. An identity submatrix structure of this type of quasi-cyclic low-density parity-check code is very suitable for hardware implementing parallel operations, for example, a decoder with a high degree of parallelism and a high throughput rate. There is a parity-check matrix with a dual-diagonal structure or a raptor-like structure at a parity bit part, so encoding is very simple, and an incremental redundancy hybrid automatic repeat request technology can be supported. Currently, an LDPC code technology has been widely used in major communication standards. When the LDPC code technology is used, how to determine a quantity of code blocks into which a transport block is to be segmented is a problem that a person skilled in the art is studying.

### SUMMARY

To resolve a technical problem, embodiments of the present invention provide an information processing method and apparatus, and a device, so that a quantity of code blocks obtained through calculation can meet a channel encoding requirement.

According to a first aspect, an embodiment of the present invention provides an information processing method, and the method includes: obtaining an encoding code rate of a transport block; and if a first code rate Rᵣₑₐₗ is greater than or equal to a second code rate Rₘᵢₙ, determining, based on a maximum code block length Kₘₐₓ of an LDPC, a quantity C of code blocks into which the transport block is to be segmented, where the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

In the foregoing steps, it is determined, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, a size of a buffer used by a receive end to store soft information of a code block is used, so that the quantity of code blocks obtained through calculation is more appropriate.

With reference to the first aspect, in a first possible implementation of the first aspect, the method includes: if the first code rate Rᵣₑₐₗ is less than the second code rate Rₘᵢₙ, determining, based on the first code rate Rᵣₑₐₗ and a maximum encoded length N_{CB} of a code block, the quantity C of code blocks into which the transport block is to be segmented, where

if the second code rate Rₘᵢₙ is the minimum code rate corresponding to the maximum code block length of the LDPC code, N_{CB} is a maximum encoded length Nₘₐₓ of the LDPC code; or

if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

With reference to either the first aspect or the foregoing possible implementation of the first aspect, in a second possible implementation of the first aspect, the code rate limit of the maximum code block length of the LDPC code is Kₘₐₓ/N_{CB,limit}, and N_{CB,limit} is the size of the buffer used by the receive end to store the soft information of the code block.

With reference to any one of the first aspect or the foregoing possible implementations of the first aspect, in a third possible implementation of the first aspect, the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by the receive end to store soft information of the transport block.

With reference to any one of the first aspect or the foregoing possible implementations of the first aspect, in a fourth possible implementation of the first aspect, the determining, based on a maximum code block length Kₘₐₓ of an LDPC, a quantity of code blocks into which the transport block is to be segmented includes: determining, based on the maximum code block length Kₘₐₓ of the LDPC, the quantity of code blocks into which the transport block is to be segmented, where a value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the CRC bits of the transport block, and L_{CB,CRC} is a length of CRC bits of the code block.

With reference to any one of the first aspect or the foregoing possible implementations of the first aspect, in a fifth possible implementation of the first aspect, the determining, based on the first code rate and a maximum encoded length N_{CB} of a code block, the quantity of code blocks into which the transport block is to be segmented includes: determining, based on the first code rate and the maximum encoded length N_{CB} of the code block, the quantity of code blocks into which the transport block is to be segmented, where a value of the quantity C of code blocks into which the transport block is to be segmented satisfies:

C=└(TBS+L_{TB,CRC})/(└Rᵣₑₐₗ*N_{CB}┘−L_{CB,CRC})┘, or

C=┌(TBS+L_{TB,CRC})/(└Rᵣₑₐₗ*N_{CB}┘−L_{CB,CRC})┐, where

TBS is the length of the transport block, L_{TB,CRC} is the length of the CRC bits of the transport block, and L_{CB,CRC} is a length of CRC bits of the code block.

With reference to any one of the first aspect or the foregoing possible implementations of the first aspect, in a sixth possible implementation of the first aspect, if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or

if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, where

Th is a preset threshold.

With reference to any one of the first aspect or the foregoing possible implementations of the first aspect, in a seventh possible implementation of the first aspect, the preset threshold Th is equal to 0, or the preset threshold Th is less than or equal to a difference between the maximum code block length of the LDPC and a length of └Rᵣₑₐₗ*N_{CB}┘ and is greater than 0.

According to a second aspect, an embodiment of the present invention provides an information processing method, and the method includes: determining whether a length obtained by encoding a transport block based on R_{min,K}_{ₘₐₓ} is greater than or equal to a smaller value in N_{IR} and G, where R_{min,K}_{ₘₐₓ} is a minimum code rate corresponding to a maximum code block length of an LDPC, N_{IR} is a size of a buffer used by a receive end to store soft information of the transport block, and G is a quantity of authorized bits used to transmit the transport block; and if the length obtained by encoding the transport block based on R_{min,k}_{ₘₐₓ} is greater than or equal to the smaller value in N_{IR} and G, determining, based on the maximum code block length Kₘₐₓ of the LDPC, a quantity of code blocks into which the transport block is to be segmented.

In the foregoing steps, an estimated length obtained by encoding the transport block is compared with a smaller value in a size of a buffer used by the receive end to store soft information of a code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on a length of the transport block and a minimum code rate of the LDPC. In this process, the size of the buffer used by the receive end to store the soft information of the code block is considered, so that the quantity of code blocks obtained through calculation is more appropriate.

With reference to the second aspect, in a first possible implementation of the second aspect, the method includes: if the length obtained by encoding the transport block based on R_{min,K}_{ₘₐₓ} is less than the smaller value in N_{IR} and G, determining, based on a length of the transport block and a minimum code rate of the LDPC, the quantity of code blocks into which the transport block is to be segmented.

With reference to either the second aspect or the foregoing possible implementation of the second aspect, in a second possible implementation of the second aspect, the determining, based on a length of the transport block and a minimum code rate of the LDPC, the quantity of code blocks into which the transport block is to be segmented includes: determining, based on the length of the transport block and the minimum code rate of the LDPC, the quantity of code blocks into which the transport block is to be segmented, where a value of the quantity C of code blocks into which the transport block is to be segmented satisfies:

C=┌min((TBS+L_{TB,CRC})/R_{min,K}, G, N_{IR})/N_{CB}┐, or

C=└min((TBS+L_{TB,CRC})/R_{min,K}, G, N_{IR})/N_{CB}┘, where

TBS is the length of the transport block, L_{TB,CRC} is a length of cyclic redundancy check CRC bits of the transport block, R_{min,K} is the minimum code rate of the LDPC, and N_{CB} is a smaller value in a maximum encoded length Nₘₐₓ of the LDPC code and a size of a buffer used by the receive end to store soft information of the code block.

With reference to any one of the second aspect or the foregoing possible implementations of the second aspect, in a third possible implementation of the first aspect, the determining, based on the maximum code block length Kₘₐₓ of the LDPC, a quantity of code blocks into which the transport block is to be segmented includes: determining, based on the maximum code block length Kₘₐₓ of the LDPC, the quantity of code blocks into which the transport block is to be segmented, where the value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the cyclic redundancy check CRC bits of the transport block, and L_{CB,CRC} is a length of CRC bits of the code block.

According to a third aspect, an embodiment of the present invention provides an information processing apparatus, and the apparatus includes a processor and a memory. The memory is configured to store a transport block, and the processor is configured to perform the following operations: obtaining an encoding code rate of the transport block; and if a first code rate Rᵣₑₐₗ is greater than or equal to a second code rate Rₘᵢₙ, determining, based on a maximum code block length Kₘₐₓ of an LDPC, a quantity C of code blocks into which the transport block is to be segmented, where the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

In the foregoing operations, it is determined, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, a size of a buffer used by a receive end to store soft information of a code block is used, so that the quantity of code blocks obtained through calculation is more appropriate.

With reference to the third aspect, in a first possible implementation of the third aspect, if the first code rate Rᵣₑₐₗ is less than the second code rate Rₘᵢₙ, the processor is configured to determine, based on the first code rate Rᵣₑₐₗ and a maximum encoded length N_{CB} of a code block, the quantity C of code blocks into which the transport block is to be segmented, where

if the second code rate Rₘᵢₙ is the minimum code rate corresponding to the maximum code block length of the LDPC code, N_{CB} is a maximum encoded length Nₘₐₓ of the LDPC code; or

if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

With reference to either the third aspect or the foregoing possible implementation of the third aspect, in a second possible implementation of the third aspect, the code rate limit of the maximum code block length of the LDPC code is Kₘₐₓ/N_{CB,limit}, and N_{CB,limit} is the size of the buffer used by the receive end to store the soft information of the code block.

With reference to any one of the third aspect or the foregoing possible implementations of the third aspect, in a third possible implementation of the third aspect, the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by the receive end to store soft information of the transport block.

With reference to any one of the third aspect or the foregoing possible implementations of the third aspect, in a fourth possible implementation of the third aspect, the processor is configured to determine, based on the maximum code block length Kₘₐₓ of the LDPC, the quantity of code blocks into which the transport block is to be segmented, where a value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the CRC bits of the transport block, and L_{CB,CRC} is a length of CRC bits of the code block.

With reference to any one of the third aspect or the foregoing possible implementations of the third aspect, in a fifth possible implementation of the third aspect, the processor is configured to determine, based on the first code rate and the maximum encoded length N_{CB} of the code block, the quantity of code blocks into which the transport block is to be segmented, where a value of the quantity C of code blocks into which the transport block is to be segmented satisfies:

C=└(TBS+L_{TB,CRC})/(└Rᵣₑₐₗ*N_{CB}┘−L_{CB,CRC})┘, or

C=┌(TBS+L_{TB,CRC})/(└Rᵣₑₐₗ*N_{CB}┘−L_{CB,CRC})┐, where

TBS is the length of the transport block, L_{TB,CRC} is the length of the CRC bits of the transport block, and L_{CB,CRC} is a length of CRC bits of the code block.

With reference to any one of the third aspect or the foregoing possible implementations of the third aspect, in a sixth possible implementation of the third aspect, if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or

if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, where

Th is a preset threshold.

With reference to any one of the third aspect or the foregoing possible implementations of the third aspect, in a seventh possible implementation of the third aspect, the preset threshold Th is equal to 0, or the preset threshold Th is less than or equal to a difference between the maximum code block length of the LDPC and a length of └Rᵣₑₐₗ*N_{CB}┘ and is greater than 0.

According to a fourth aspect, an embodiment of the present invention provides an information processing apparatus, and the apparatus includes a processor and a memory. The memory is configured to store a program, and the processor is configured to execute the program in the memory, to perform the following operations: obtaining an encoding code rate of the transport block; and if a first code rate Rᵣₑₐₗ is greater than or equal to a second code rate Rₘᵢₙ, determining, based on a maximum code block length Kₘₐₓ of an LDPC, a quantity C of code blocks into which the transport block is to be segmented, where the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

In the foregoing operations, it is determined, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, a size of a buffer used by a receive end to store soft information of a code block is used, so that the quantity of code blocks obtained through calculation is more appropriate.

With reference to the fourth aspect, in a first possible implementation of the fourth aspect, if the first code rate Rᵣₑₐₗ is less than the second code rate Rₘᵢₙ, the processor is configured to determine, based on the first code rate Rᵣₑₐₗ and a maximum encoded length N_{CB} of a code block, the quantity C of code blocks into which the transport block is to be segmented, where

if the second code rate Rₘᵢₙ is the minimum code rate corresponding to the maximum code block length of the LDPC code, N_{CB} is a maximum encoded length Nₘₐₓ of the LDPC code; or

if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

With reference to either the fourth aspect or the foregoing possible implementation of the fourth aspect, in a second possible implementation of the fourth aspect, the code rate limit of the maximum code block length of the LDPC code is Kₘₐₓ/N_{CB,limit}, and N_{CB,limit} is the size of the buffer used by the receive end to store the soft information of the code block.

With reference to any one of the fourth aspect or the foregoing possible implementations of the fourth aspect, in a third possible implementation of the fourth aspect, the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by the receive end to store soft information of the transport block.

With reference to any one of the fourth aspect or the foregoing possible implementations of the fourth aspect, in a fourth possible implementation of the fourth aspect, the processor is configured to determine, based on the maximum code block length Kₘₐₓ of the LDPC, the quantity of code blocks into which the transport block is to be segmented, where a value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the CRC bits of the transport block, and L_{CB,CRC} is a length of CRC bits of the code block.

With reference to any one of the fourth aspect or the foregoing possible implementations of the fourth aspect, in a fifth possible implementation of the fourth aspect, the processor is configured to determine, based on the first code rate and the maximum encoded length N_{CB} of the code block, the quantity of code blocks into which the transport block is to be segmented, where a value of the quantity C of code blocks into which the transport block is to be segmented satisfies:

C=└(TBS+L_{TB,CRC})/(└Rᵣₑₐₗ*N_{CB}┘−L_{CB,CRC})┘, or

C=┌(TBS+L_{TB,CRC})/(└Rᵣₑₐₗ*N_{CB}┘−L_{CB,CRC})┐, where

TBS is the length of the transport block, L_{TB,CRC} is the length of the CRC bits of the transport block, and L_{CB,CRC} is a length of CRC bits of the code block.

With reference to any one of the fourth aspect or the foregoing possible implementations of the fourth aspect, in a sixth possible implementation of the fourth aspect, if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or

if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, where

Th is a preset threshold.

With reference to any one of the fourth aspect or the foregoing possible implementations of the fourth aspect, in a seventh possible implementation of the fourth aspect, the preset threshold Th is equal to 0, or the preset threshold Th is less than or equal to a difference between the maximum code block length of the LDPC and a length of └Rᵣₑₐₗ*N_{CB}┘ and is greater than 0.

According to a fifth aspect, an embodiment of the present invention provides an information processing apparatus, and the apparatus includes a processor and a memory. The memory is configured to store a transport block, and the processor is configured to perform the following operations: determining whether a length obtained by encoding the transport block based on R_{min,K}_{ₘₐₓ} is greater than or equal to a smaller value in N_{IR} and G, where R_{min,K}_{ₘₐₓ} is a minimum code rate corresponding to a maximum code block length of an LDPC, N_{IR} is a size of a buffer used by a receive end to store soft information of the transport block, and G is a quantity of authorized bits used to transmit the transport block; and if the length obtained by encoding the transport block based on R_{min,K}_{ₘₐₓ} is greater than or equal to the smaller value in N_{IR} and G, determining, based on the maximum code block length Kₘₐₓ of the LDPC, a quantity of code blocks into which the transport block is to be segmented.

In the foregoing operations, an estimated length obtained by encoding the transport block is compared with a smaller value in a size of a buffer used by the receive end to store soft information of a code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on a length of the transport block and a minimum code rate of the LDPC. In this process, the size of the buffer used by the receive end to store the soft information of the code block is considered, so that the quantity of code blocks obtained through calculation is more appropriate.

With reference to the fifth aspect, in a first possible implementation of the fifth aspect, if the length obtained by encoding the transport block based on R_{min,k}_{ₘₐₓ} is less than the smaller value in N_{IR} and G, the processor is configured to determine, based on a length of the transport block and a minimum code rate of the LDPC, the quantity of code blocks into which the transport block is to be segmented.

With reference to either the fifth aspect or the foregoing possible implementation of the fifth aspect, in a second possible implementation of the fifth aspect, the processor is configured to determine, based on the length of the transport block and the minimum code rate of the LDPC, the quantity of code blocks into which the transport block is to be segmented, where a value of the quantity C of code blocks into which the transport block is to be segmented satisfies:

C=┌min((TBS+L_{TB,CRC})/R_{min,K}, G, N_{IR})/N_{CB}┐, or

C=└min((TBS+L_{TB,CRC})/R_{min,K}, G, N_{IR})/N_{CB}┘, where

TBS is the length of the transport block, L_{TB,CRC} is a length of cyclic redundancy check CRC bits of the transport block, R_{min,K} is the minimum code rate of the LDPC, and N_{CB} is a smaller value in a maximum encoded length Nₘₐₓ of the LDPC code and a size of a buffer used by the receive end to store soft information of the code block.

With reference to any one of the fifth aspect or the foregoing possible implementations of the fifth aspect, in a third possible implementation of the fifth aspect, the processor is configured to determine, based on the maximum code block length Kₘₐₓ of the LDPC, the quantity of code blocks into which the transport block is to be segmented, where the value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the cyclic redundancy check CRC bits of the transport block, and L_{CB,CRC} is a length of CRC bits of the code block.

According to a sixth aspect, an embodiment of the present invention provides an information processing apparatus, and the apparatus includes a processor and a memory. The memory is configured to store a program, and the processor invokes the program in the memory, to perform the following operations: determining whether a length obtained by encoding a transport block based on R_{min,K}_{ₘₐₓ} is greater than or equal to a smaller value in N_{IR} and G, where R_{min,K}_{ₘₐₓ} is a minimum code rate corresponding to a maximum code block length of an LDPC, N_{IR} is a size of a buffer used by a receive end to store soft information of the transport block, and G is a quantity of authorized bits used to transmit the transport block; and if the length obtained by encoding the transport block based on R_{min,K}_{ₘₐₓ} is greater than or equal to the smaller value in N_{IR} and G, determining, based on the maximum code block length Kₘₐₓ of the LDPC, a quantity of code blocks into which the transport block is to be segmented.

In the foregoing operations, an estimated length obtained by encoding the transport block is compared with a smaller value in a size of a buffer used by the receive end to store soft information of a code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on a length of the transport block and a minimum code rate of the LDPC. In this process, the size of the buffer used by the receive end to store the soft information of the code block is considered, so that the quantity of code blocks obtained through calculation is more appropriate.

With reference to the sixth aspect, in a first possible implementation of the sixth aspect, if the length obtained by encoding the transport block based on R_{min,K}_{ₘₐₓ} is less than the smaller value in N_{IR} and G, the processor is configured to determine, based on a length of the transport block and a minimum code rate of the LDPC, the quantity of code blocks into which the transport block is to be segmented.

With reference to either the sixth aspect or the foregoing possible implementation of the sixth aspect, in a second possible implementation of the sixth aspect, the processor is configured to determine, based on the length of the transport block and the minimum code rate of the LDPC, the quantity of code blocks into which the transport block is to be segmented, where a value of the quantity C of code blocks into which the transport block is to be segmented satisfies:

C=┌min((TBS+L_{TB,CRC})/R_{min,K}, G, N_{IR})/N_{CB}┐, or

C=└min((TBS+L_{TB,CRC})/R_{min,K}, G, N_{IR})/N_{CB}┘, where

TBS is the length of the transport block, L_{TB,CRC} is a length of cyclic redundancy check CRC bits of the transport block, R_{min,K} is the minimum code rate of the LDPC, and N_{CB} is a smaller value in a maximum encoded length Nₘₐₓ of the LDPC code and a size of a buffer used by the receive end to store soft information of the code block.

With reference to any one of the sixth aspect or the foregoing possible implementations of the sixth aspect, in a third possible implementation of the sixth aspect, the processor is configured to determine, based on the maximum code block length Kₘₐₓ of the LDPC, the quantity of code blocks into which the transport block is to be segmented, where the value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the cyclic redundancy check CRC bits of the transport block, and L_{CB,CRC} is a length of CRC bits of the code block.

According to a seventh aspect, an embodiment of the present invention provides a device, and the device includes the apparatus in either the third aspect or the fourth aspect.

According to an eighth aspect, an embodiment of the present invention provides a device, and the device includes the apparatus in either the fifth aspect or the sixth aspect.

According to a ninth aspect, an embodiment of the present invention provides a storage medium. The storage medium is configured to store an instruction, and when the instruction runs on a computer, the method in any one of the first aspect or the possible implementations of the first aspect is performed.

According to a tenth aspect, an embodiment of the present invention provides a storage medium. The storage medium is configured to store an instruction, and when the instruction runs on a computer, the method in any one of the second aspect or the possible implementations of the second aspect is performed.

In the embodiments of the present invention, it is determined, based on the relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, the size of the buffer used by the receive end to store the soft information of the code block is used, so that the quantity of code blocks obtained through calculation is more appropriate.

### BRIEF DESCRIPTION OF DRAWINGS

To describe the technical solutions in the embodiments of the present invention or in the background more clearly, the following briefly describes the accompanying drawings required for describing the embodiments of the present invention or the background.

FIG. 1 is a schematic diagram of a segmentation scenario of a transport block and a code block in the prior art;

FIG. 2 is a schematic diagram of a turbo code interleaver parameter table in the prior art;

FIG. 3 is a schematic structural diagram of a communications system according to an embodiment of the present invention;

FIG. 4 is a schematic flowchart of an information processing method according to an embodiment of the present invention;

FIGS. 5(a) and (b) are schematic diagrams of a rate matching scenario according to an embodiment of the present invention;

FIGS. 6(a) and (b) are schematic diagrams of comparison between information processing effects according to an embodiment of the present invention;

FIG. 7 is a schematic flowchart of another information processing method according to an embodiment of the present invention;

FIG. 8 is a schematic structural diagram of an apparatus according to an embodiment of the present invention;

FIG. 9 is a schematic structural diagram of another apparatus according to an embodiment of the present invention;

FIG. 10 is a schematic structural diagram of another apparatus according to an embodiment of the present invention; and

FIG. 11 is a schematic structural diagram of another apparatus according to an embodiment of the present invention.

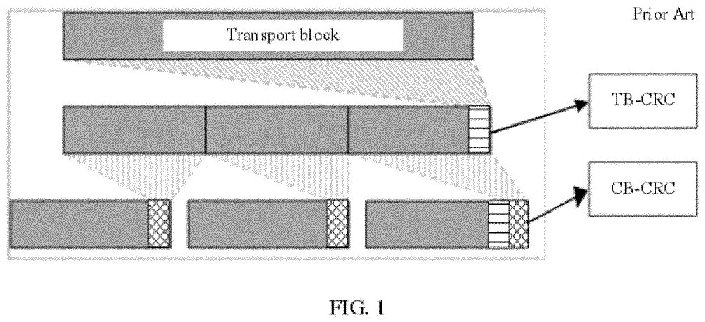

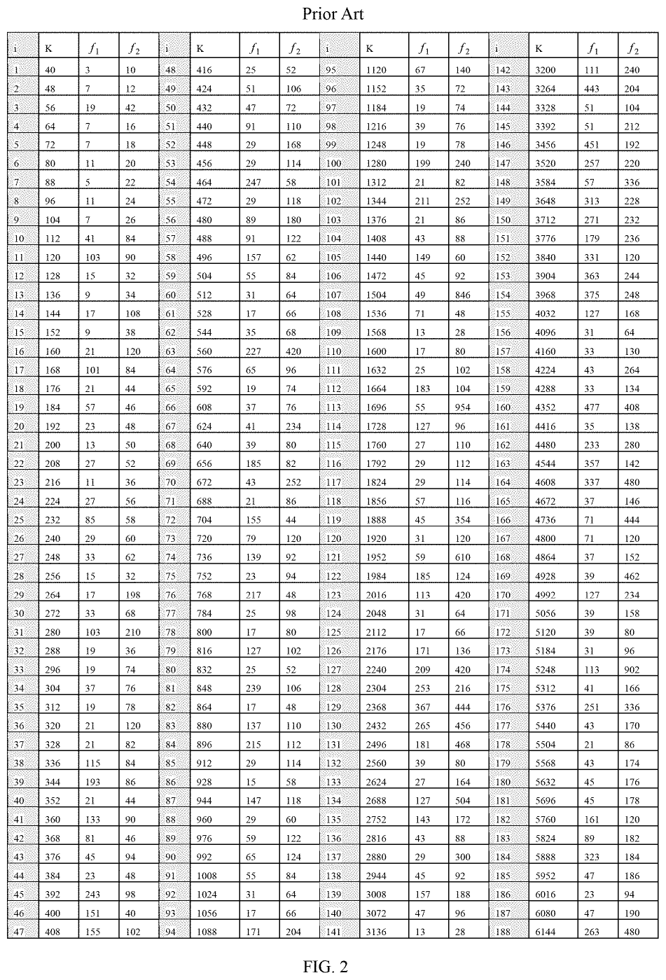

### DESCRIPTION OF EMBODIMENTS

The following describes the embodiments of the present invention with reference to the accompanying drawings in the embodiments of the present invention.

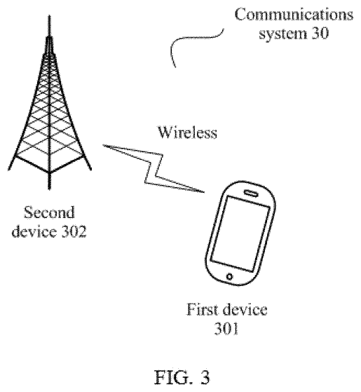

FIG. 3 is a schematic structural diagram of a communications system 30 according to an embodiment of the present invention. The system 30 includes a first device 301 and a second device 302. The first device 301 may communicate with the second device 302, and data sent in the communication process needs to be encoded. Information received by a receive end needs to be decoded to restore information before encoding by a transmit end. When the first device 301 functions as the transmit end, the second device 302 may function as the receive end. When the first device 301 functions as the receive end, the second device 302 may function as the transmit end. Both the first device 301 and the second device 302 may play different roles at different moments, for example, the first device 301 and the second device 302 each function as the receive end at a moment, and function as the transmit end at another moment. Optionally, the first device 301 may be user equipment in a cellular network. The user equipment may be a mobile phone, a tablet computer, a notebook computer, a palmtop computer, a mobile internet device (MID), a wearable device (for example, a smartwatch (such as an iWatch), a smart band, or a pedometer), or the like. The second device 302 may be a network side device in the cellular network, for example, may be an eNodeB (eNB). When the communications system is a communications system based on a fifth-generation mobile communications technology (5G), the second device 302 may be a gNB (gNB) applicable to new radio (NR). In a communications system based on another technology, the network device 301 may have another name. Examples are not enumerated herein.

The first device needs to calculate, based on a size TBS of a to-be-sent transport block and other related information, a quantity of code blocks into which the transport block needs to be segmented and a size (or referred to as a “length”) of each code block. After obtaining the quantity of code blocks and the length of each code block through calculation, the first device segments the transport block based on the quantity and the length. After completing the segmentation, the first device independently encodes each code block and performs rate matching on each code block, and then performs a code block concatenation operation on the code blocks to combine the code blocks into one piece of information. This piece of information obtained through combination may be referred to as a target information. The first device sends the target information to the second device.

The second device receives the target information. The second device also needs to calculate, based on the size TBS of the transport block and other related information, the quantity of code blocks into which the transport block needs to be segmented, the size (or referred to as the “length”) of each code block, and a length obtained after rate matching of the transport block (which is the same as that performed by a rate matching module at the transmit end). Then the second device segments the target information based on the quantity of code blocks and the length of each code block that are obtained through calculation, and separately performs rate dematching, decoding, and a code block concatenation operation on code blocks obtained through segmentation, to restore data of the TBS.

It can be learned from the foregoing description that, both the first device and the second device need to calculate the quantity of code blocks into which the transport block is to be segmented, and a calculation rule may be agreed upon in advance according to a same protocol, so that the first device and the second device obtain a same result. In addition, the information used in the calculation process may be partially predefined in the protocol, or may be partially notified between the first device and the second device through communication. For example, the first device may send length information of the transport block to the second device, for use by the second device during subsequent calculation. In the following embodiments of the present invention, the first device is mainly used as an example to describe, by using the following several possible method procedures, how to calculate the quantity of code blocks into which the transport block is to be segmented. A calculation manner used by the second device to calculate the quantity of code blocks into which the transport block is to be segmented is the same as that used by the first device. Therefore, no additional description is provided in the embodiments of the present invention.

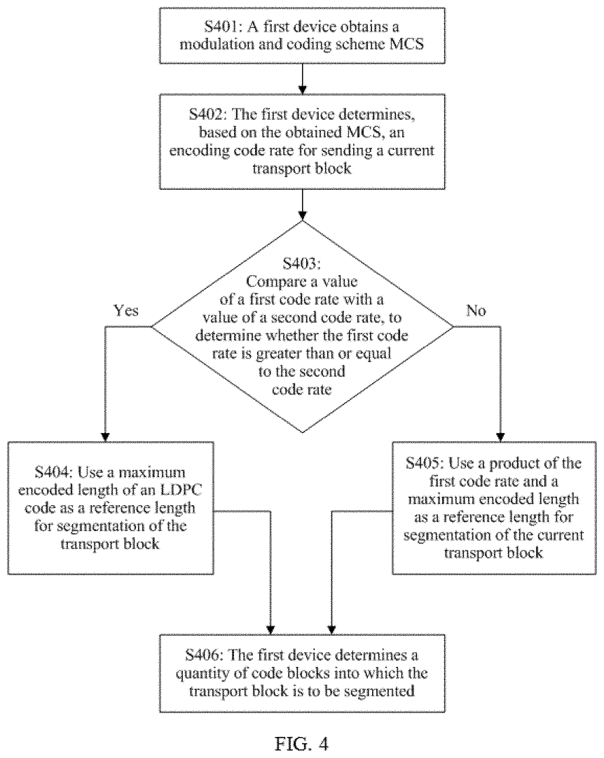

FIG. 4 is a schematic flowchart of an information processing method according to an embodiment of the present invention. The method includes but is not limited to the following steps.

Step S401: A first device obtains a current modulation and coding scheme (MCS).

Specifically, the first device may determine the current modulation and coding scheme MCS based on a current channel status. Usually, if the channel status is good, the first device may select a high code rate and higher-order modulation, and if the channel status is not good, the first device may select a low code rate and lower-order modulation.

Step S402: The first device determines, based on the obtained MCS, an encoding code rate for sending a transport block.

Specifically, the first device prestores correspondences between a plurality of MCSs and a plurality of code rates. After determining a modulation and coding scheme MCS, the first device may determine a code rate corresponding to the modulation and coding scheme MCS based on the correspondence. In other words, the first device may obtain the encoding code rate R of the transport block based on the MCS.

Step S403: The first device compares a value of a first code rate with a value of a second code rate.

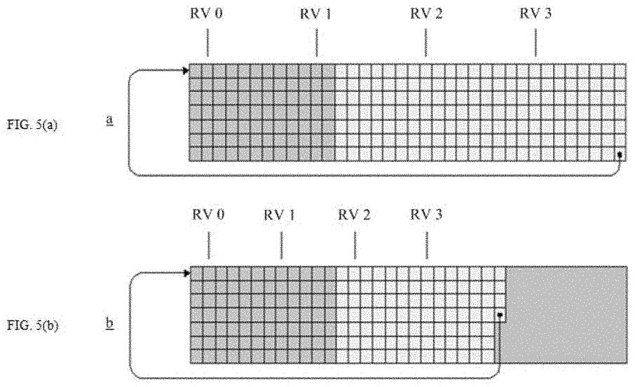

Specifically, bit information obtained after the transport block TB is segmented and encoded is transmitted to a receive end, and the receive end may input the information into a register. Limited buffer cases may exist in the register, for example, a transport block TB limited buffer case and a code block CB limited buffer case. The transport block TB limited buffer specifically means that there is an upper limit value for memory resources occupied in the register by bits information obtained by encoding the entire transport block. In other words, a size of a buffer used by the receive end to store soft information of the transport block may also be referred to as a transport block buffer upper limit N_{IR}. The code block CB limited buffer specifically means that there is an upper limit value for memory resources occupied in the register by bits information obtained by encoding a code block. In other words, a size of a buffer used by the receive end to store soft information of the code block may also be referred to as a code block buffer upper limit N_{CB,limit}. As shown in FIGS. 5(a) and (b) (which is merely an example), FIG. 5(a) shows rate matching of a code block in a case of an unlimited buffer, and FIG. 5(b) shows rate matching of a code block in a case of a limited buffer. The limited buffer is mainly reflected by limited buffer resources. Available buffer resources of the limited buffer are usually fewer than available buffer resources of the unlimited buffer.

In different cases, the first code rate and the second code rate may be calculated in different manners. Examples are shown as follows:

When a transport block TB buffer is limited, the first device may calculate the first code rate based on a length of the transport block and the transport block buffer upper limit N_{IR}. For example, a calculation formula may be Rᵣₑₐₗ=max{R,(TBS+L_{TB,CRC})/N_{IR}, R_{min,K}}, where Rᵣₑₐₗ is the first code rate, TBS is the length of the transport block, L_{TB,CRC} is a length of cyclic redundancy check CRC bits of the transport block, N_{IR} is the transport block buffer upper limit, (TBS+L_{TB,CRC})/N_{IR} is a code rate obtained through calculation based on the transport block buffer upper limit N_{IR}, and may be referred to as a code rate limit, and R_{min,K} is a minimum code rate of an LDPC code. The transport block buffer upper limit may be sent by the first device to a second device, or may be predefined in a communication protocol of the first device and a second device, or may be learned of by the first device in another manner.

When a code block CB buffer is limited, the first device may calculate the second code rate based on a maximum code block length of the LDPC and the code block buffer upper limit N_{CB,limit}. For example, a calculation formula may be Rₘᵢₙ=max(R_{min,K}_{ₘₐₓ}, Kₘₐₓ/N_{CB,limit}), where Rₘᵢₙ is the second code rate, R_{min,K}_{ₘₐₓ} is a minimum code rate corresponding to a maximum code block length of the LDPC, Kₘₐₓ is the maximum code block length of the LDPC, and N_{CB,limit} is the code block buffer upper limit. The code block buffer upper limit N_{CB,limit} may be sent by the first device to the second device, or may be predefined in the communication protocol of the first device and the second device, or may be learned of by the first device in another manner. In addition, this embodiment of the present invention further relates to a maximum encoded length Nₘₐₓ (the maximum number of variable nodes (after lifting) of any parity check matrix, Nₘₐₓ) of the LDPC code. Usually, a system authorizes the maximum encoded length Nₘₐₓ to indicate that the soft information of the code block cannot exceed the maximum encoded length Nₘₐₓ. When the code block buffer upper limit N_{CB,limit} exists, a length obtained by encoding the code block actually cannot exceed N_{CB,limit} or Nₘₐₓ. Therefore, N_{CB}=min{Nₘₐₓ, N_{CB,limit}}, to be specific, an actual maximum encoded length N_{CB} is a smaller value in Nₘₐₓ authorized by the system and N_{CB,limit}.

In an optional solution, the first code rate satisfies the following condition Rᵣₑₐₗ=max{R, (TBS+L_{TB,CRC})/N_{IR}, R_{min,K}}, where (TBS+L_{TB,CRC})/N_{IR} may be referred to as a code rate limit of the transport block, R_{min,K} is a minimum code rate of an LDPC code (a minimum code rate supported by the LDPC code), TBS is a length of the transport block, L_{TB,CRC} is a length of cyclic redundancy check CRC bits of the transport block. Optionally, numerous values for measuring a code block length are predefined for the LDPC code, and each value for measuring a code block length corresponds to one code rate range. If a length of a code block is exactly equal to the value for measuring a code block length, the code block may be encoded based on a code rate in the code rate range corresponding to the value for measuring a code block length. It may be understood that, there is a largest value in the numerous values for measuring a code block length that are predefined in the LDPC code, and the largest value may be referred to as a maximum code block length of the LDPC. There is a minimum code rate in a code rate range corresponding to the maximum code block length of the LDPC.

In an optional solution, the second code rate is a minimum code rate corresponding to the maximum code block length of the LDPC code, or a larger one between a minimum code rate corresponding to the maximum code block length of the LDPC code and a code rate limit of the maximum code block length of the LDPC code. When the second code rate is the larger one between the minimum code rate corresponding to the maximum code block length of the LDPC code and the code rate limit of the maximum code block length of the LDPC code, the second code rate satisfies the following condition Rₘᵢₙ=max(R_{min,K}_{ₘₐₓ}, Kₘₐₓ/N_{CB,limit}), and Kₘₐₓ/N_{CB,limit} may be referred to as the code rate limit of the maximum code block length of the LDPC code.

Step S404: If the first code rate is greater than or equal to the second code rate, the first device uses a maximum code block length of the LDPC code as a reference length for segmentation of the transport block.

In other words, if Rᵣₑₐₗ≥Rₘᵢₙ, it is determined that the reference length for segmentation of the transport block is K_{GB,max=}Kₘₐₓ.

Step S405: If the first code rate is less than the second code rate, the first device uses a product of the first code rate and a maximum encoded length N_{CB} of a code block as a reference length for segmentation of the transport block.

In other words, if Rᵣₑₐₗ<Rₘᵢₙ, it is determined that the reference length for segmentation of the transport block is K_{GB,max=}└N_{CB}*Rᵣₑₐₗ┘.

Step S406: The first device determines a quantity of code blocks into which the transport block is to be segmented.

Specifically, the first device may perform step S406 after performing step S404 or step S405. The quantity of code blocks into which the transport block is to be segmented is determined before specific segmentation. In other words, after the quantity of code blocks into which the transport block is to be segmented is determined, the segmentation is performed based on information about the quantity. A determining manner may be as follows: Relative values of a sum TBS+L_{TB,CRC} of the length TBS of the transport block and the length L_{TB,CRC} of the cyclic redundancy check CRC bits of the transport block and the reference length K_{CB,max} are compared. If TBS+L_{TB,CRC}≤K_{CB,max}, the transport block does not need to be segmented, to be specific, the quantity C of code blocks CBs is C=1, and a length of the code block is K=TBS+L_{TB,CRC}. If TBS+L_{TB,CRC}>K_{CB,max}, further determining needs to be performed. A determining manner is as follows:

It is determined whether a remainder obtained by dividing a first parameter by a second parameter is less than a preset threshold Th. The first parameter is a parameter obtained through calculation based on the length (Transport Block Size, TBS) of the transport block. The second parameter is a parameter obtained through calculation based on the reference length K_{CB,max}. If the remainder is less than the preset threshold Th, the quantity of code blocks into which the transport block is to be segmented is equal to a rounded-down value obtained by dividing the first parameter by the second parameter. If the remainder is greater than the preset threshold Th, the quantity of code blocks into which the transport block is to be segmented is equal to a rounded-up value obtained by dividing the first parameter by the second parameter. In an optional solution, if the remainder obtained by dividing the first parameter by the second parameter is equal to the preset threshold Th, the quantity of code blocks into which the transport block is to be segmented is equal to a rounded-down value obtained by dividing the first parameter by the second parameter. In another optional solution, if the remainder obtained by dividing the first parameter by the second parameter is equal to the preset threshold Th, the quantity of code blocks into which the transport block is to be segmented is equal to a rounded-up value obtained by dividing the first parameter by the second parameter.

Optionally, the first parameter is equal to the sum TBS+L_{TB,CRC} of the length TBS of the transport block and the length L_{TB,CRC} of the cyclic redundancy check of the transport block, and the second parameter is equal to a difference K_{CB,max}−L_{CB,CRC} between the reference length K_{CB,max} and a length L_{CB,CRC} of cyclic redundancy check CRC bits of the code block.

In other words, if (TBS+L_{TB,CRC})mod(K_{CB,max}−L_{CB,CRC})<Th, a value of C satisfies C=└(TBS+L_{TB,CRC})/(K_{CB,max}−L_{CB,CRC})┘. In this case, if the transport block is segmented in units of K_{CB,max}, a small part of bit information may remain. If one extra code block is obtained through segmentation due to this small part of extra information, a quantity of code blocks obtained through segmentation is relatively large. In general, it is not worthwhile to obtain one extra block through segmentation due to this small part of extra bit information.

If (TBS+L_{TB,CRC})mod(K_{CB,max}−L_{CB,CRC})≥Th, a value of C satisfies C=┌(TBS+L_{TB,CRC})/(K_{CB,max}−L_{CB,CRC})┐. In this case, if the transport block is segmented in units of K_{CB,max}, a relatively large amount of bit information may remain. In this case, one extra code block may be obtained through segmentation by performing rounding up, so that the relatively large amount of bit information can be effectively transmitted.

It should be noted that, the preset threshold Th may be a parameter that is preconfigured based on an actual situation and that is used for comparison. Optionally, the preset threshold Th is less than or equal to a difference between the maximum code block length Kₘₐₓ of the LDPC and the reference length K_{CB,max} and is greater than 0. In other words, 0<Th≤Kₘₐₓ−K_{CB,max}.

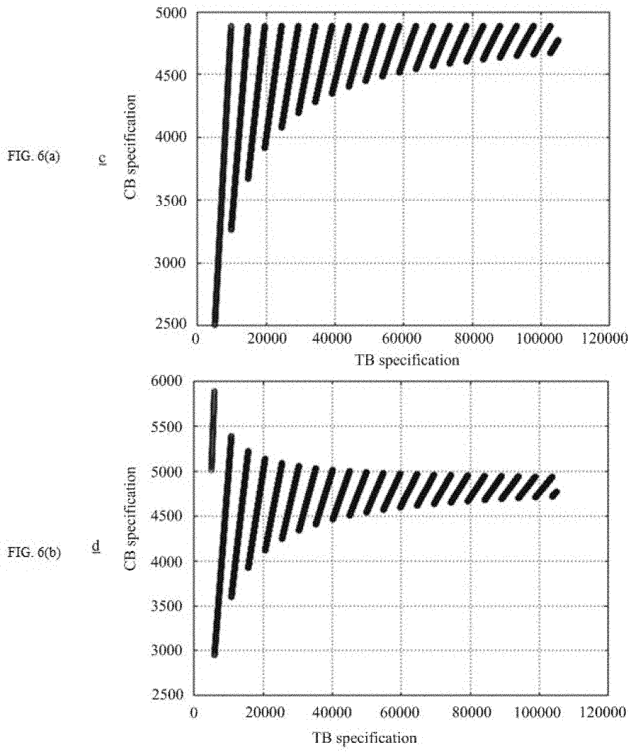

For ease of understanding, a specific example is used below for description. It is assumed that TBS=19600, L_{TB,CRC}=24, K_{CB,max}=4915, Kₘₐₓ=6144, L_{CB,CRC}=24, and Th=100. When the defined maximum code block length of the LDPC code is K_{CB,max}=4915 bits, the corresponding minimum code rate is equal to 1/5. Based on these values, TBS+L_{TB,CRC}>K_{CB,max} may be obtained. Therefore, it may be determined that the transport block is to be segmented into a plurality of code blocks. Based on these values, (TBS+L_{TB,CRC})mod(K_{CB,max}−L_{CB,CRC})=60 may be further obtained. Because Th=100, (TBS+L_{TB,CRC})mod(K_{CB,max}−L_{CB,CRC})<Th is satisfied. Therefore, C=└(TBS+L_{TB,CRC})/(K_{CB,max}−L_{CB,CRC})┘=4. It may be understood that, if the transport block is to be segmented into four code blocks, a length of each code block is equal to (19600+24)/4=4906 bits, and after a CB CRC is added, a length of each code block is 4930 bits. The length of 4930 bits is slightly greater than K_{CB,max}. In addition, it may be learned through calculation that a code rate at which the code block having the length of 4930 bits is encoded is approximately equal to (4930)/(4915/(1/5))=0.2006, and this is very close to the code rate 1/5. Therefore, in terms of a code rate, there is no big difference in subsequent encoding, regardless of a 4915-bit code block or a 4930-bit code block obtained through segmentation. However, in terms of a quantity of code blocks obtained through segmentation, in this embodiment of the present invention, the quantity of code blocks obtained through segmentation is smaller, so that subsequent encoding performance can be improved. As shown in FIGS. 6(a) and (b), FIG. 6(a) shows a relationship between a size TBS of a transport block and a size CBS of a code block obtained through segmentation in the prior art, and FIG. 6(b) shows a relationship between a size TBS of a transport block and a size CBS of a code block obtained through segmentation in this embodiment of the present invention. It can be learned that, in this embodiment of the present invention, a larger block length is used at a critical point, and the length of the code block obtained through segmentation is overall closer to the block length of 4915 bits corresponding to the code rate 1/5, thereby avoiding a performance loss caused by an excessively short code block length and an excessively large quantity of blocks obtained through segmentation.

In addition, during code block segmentation, there may be a code block group (CB Group) segmentation method, to be specific, several code blocks are used as a group and a CBG CRC is added to the group. In this case, a length CG*L_{CBG,CRC} of cyclic redundancy check CRC bits of all code block groups further needs to be added to a length (TBS+L_{TB,CRC}) of the transport block before segmentation, where CG is a code block group quantity, and L_{CBG,CRC} is a length of cyclic redundancy check CRC bits of a code block group. For example, during calculation of the code rate limit of the transport block, (TBS+L_{TB,CRC}+CG*L_{CBG,CRC})/N_{IR} is used. For another example, C=(TBS+L_{TB,CRC}+CG*L_{CBG,CRC})/(K_{CB,max}−L_{CB,CRC})┘.

In the method in shown FIG. 4, the first device determines, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, the size of the buffer used by the receive end to store the soft information of the code block is used, so that the quantity of code blocks obtained through calculation is more appropriate.

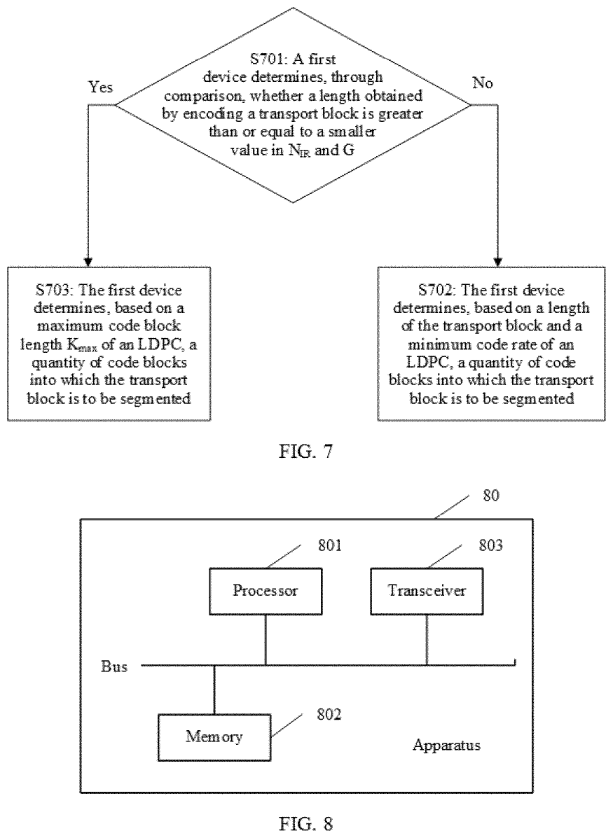

FIG. 7 is a schematic flowchart of another information processing method according to an embodiment of the present invention. The method includes but is not limited to the following steps.

Step S701: A first device compares a value of a length obtained by encoding a transport block based on R_{min,K}_{ₘₐₓ} with a smaller value in N_{IR} and G.

Specifically, the length obtained by encoding the transport block based on R_{min,K}_{ₘₐₓ} may be calculated based on a third parameter and R_{min,K}_{ₘₐₓ}. The third parameter is equal to a length TBS of the transport block or a value obtained through calculation based on a length TBS of the transport block. When the third parameter is the value obtained through calculation based on the length TBS of the transport block, optionally, the third parameter is equal to a sum of the length TBS of the transport block and a length L_{TB,CRC} of cyclic redundancy check CRC bits of the transport block. This may be expressed in the following formula: the third parameter X3=TBS+L_{TB,CRC}. A value obtained by dividing the third parameter X3 by R_{min,K}_{ₘₐₓ} is equal to the length obtained by encoding the transport block based on R_{min,K}_{ₘₐₓ}.

It should be noted that, numerous values for measuring a code block length may be predefined in an LDPC code, and each value for measuring a code block length corresponds to one code rate range. If a length of a code block is exactly equal to the value for measuring a code block length, the code block may be encoded based on a code rate in the code rate range corresponding to the value for measuring a code block length. It may be understood that, there is a largest value in the numerous values for measuring a code block length that are predefined in the LDPC code, and the largest value may be referred to as a maximum code block length of the LDPC. There is a minimum code rate R_{min,K}_{ₘₐₓ} in a code rate range corresponding to the maximum code block length Kₘₐₓ of the LDPC.

It should be noted that, R_{min,K}_{ₘₐₓ} is the minimum code rate corresponding to the maximum code block length of the LDPC, N_{IR} is a size of a buffer used by a receive end to store soft information of the transport block, and G is a quantity of authorized bits used to transmit the transport block. N_{IR} and G may be defined in a communication protocol of a transmit end and the receive end, so that both the transmit end and the receive end can learn of N_{IR} and G. Alternatively, N_{IR} and G may be configured at the receive end, so that if a transmit end needs to learn of N_{IR} and G, the receive end may send N_{IR} and G to the transmit end.

Step 5702: If the length obtained by encoding the transport block based on R_{min,K}_{ₘₐₓ} is greater than or equal to the smaller value in N_{IR} and G, the first device determines, based on a maximum code block length Kₘₐₓ of an LDPC, a quantity of code blocks into which the transport block is to be segmented.

Specifically, a rounded-up value obtained by dividing the third parameter by a fourth parameter may be determined as the quantity of code blocks CBs into which the transport block is to be segmented. Optionally, the fourth parameter is equal to the maximum code block length of the LDPC code or a value obtained through calculation based on the maximum code block length of the LDPC. When the fourth parameter is equal to the value obtained through calculation based on the maximum code block length Kₘₐₓ of the LDPC, optionally, the fourth parameter is equal to a sum of the maximum code block length Kₘₐₓ of the LDPC and a length L_{CB,CRC} of cyclic redundancy check CRC bits of the code block. This may be expressed in the following formula: the fourth parameter X4=Kₘₐₓ+L_{CS,CRC}.

It may be understood that, when a size of the transport block is relatively large, the transport block needs to be segmented before transmission to obtain code blocks that have sizes smaller than that of the transport block. A quantity of code blocks into which the transport block is to be segmented needs to be determined before formal segmentation. It can be learned from the foregoing description that, in an optional solution, if (TBS+L_{TB,CRC})/R_{min,K}_{ₘₐₓ}≥min(G, N_{IR}), the quantity of code blocks is C=┌(TBS+L_{TB,CRC})/(Kₘₐₓ−L_{CB,CRC})┐.

Step S703: If the length obtained by encoding the transport block based on R_{min,K}_{ₘₐₓ} is less than the smaller value in N_{IR} and G, the first device determines, based on a length of the transport block and a minimum code rate of an LDPC, a quantity of code blocks into which the transport block is to be segmented.

Specifically, the first device calculates, based on a value obtained by dividing the third parameter by the minimum code rate of the LDPC, the quantity of code blocks into which the transport block is to be segmented.

Specifically, the minimum code rate of the LDPC is a minimum code rate supported by the LDPC code, and may be denoted by R_{min,K}. For ease of subsequent description, the value obtained by dividing the third parameter by the minimum code rate of the LDPC may be referred to as a fifth parameter. In other words, the fifth parameter X5=(TBS+L_{TB,CRC})/R_{min,K}. The quantity of code blocks into which the transport block is to be segmented may be calculated based on the fifth parameter.

In an optional solution, a rounded-up value obtained by dividing a smallest value in the fifth parameter, N_{IR}, and G by a sixth parameter is determined as the quantity of code blocks into which the transport block is to be segmented. The sixth parameter N_{CB} is equal to a smaller value in a size N_{CB,limit} of a buffer used by the receive end to store soft information of the code block and a maximum encoded length Nₘₐₓ of the LDPC code. N_{CB,limit} and Nₘₐₓ may be defined in the communication protocol of the transmit end and the receive end, so that both the transmit end and the receive end can learn of N_{CB,limit} and Nₘₐₓ. Alternatively, N_{CB,limit} and Nₘₐₓ may be configured at the receive end, so that if the transmit end needs to learn of N_{CB,limit} and Nₘₐₓ, the receive end may send N_{CB,limit} and Nₘₐₓ to the transmit end. It can be learned from the foregoing description that, if (TBS+L_{TB,CRC})/R_{min,K}_{ₘₐₓ}<min(G, N_{IR})), the quantity of code blocks is ┌min((TBS+L_{TB,CRC})/R_{min,K}, G, N_{IR})/N_{CB}┐. In other words, the smallest value in G, N_{IR}, and the fifth parameter X5 is used, and a rounded-up value obtained by dividing the smallest value by the sixth parameter is used as the quantity of code blocks into which the transport block needs to be segmented.

In addition, during code block segmentation, there may be a code block group (CB Group) segmentation method, to be specific, several code blocks are used as a group and a CBG CRC is added to the group. In this case, a length CG*L_{CBG,CRC} of cyclic redundancy check CRC bits of all code block groups further needs to be added to a length (TBS+L_{TB,CRC}) of the transport block before segmentation, where CG is a code block group quantity, and L_{CBG,CRC} is a length of cyclic redundancy check CRC bits of a code block group. For example, the fifth parameter X5=(TBS+L_{TB,CRC}+CG*L_{CBG,CRC})/R_{min,K}. For another example, C=┌min((TBS+L_{TB,CRC}+CG*L_{CBG,CRC})/R_{min,K}, G, N_{IR})/N_{CB}┐.

In the method in shown FIG. 7, the first device compares an estimated length obtained by encoding the transport block with a smaller value in the size of the buffer used by the receive end to store the soft information of the code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on the length of the transport block and the minimum code rate of the LDPC. In this process, the size of the buffer used by the receive end to store the soft information of the code block is considered, so that the quantity of code blocks obtained through calculation is more appropriate.

The method in the embodiments of the present invention is described in detail above. An apparatus in the embodiments of the present invention is provided below.

FIG. 8 shows an apparatus 80 according to an embodiment of the present invention. The apparatus 80 includes a processor 801, a memory 802, and a transceiver 803. The processor 801, the memory 802, and the transceiver 803 are interconnected through a bus.

The memory 802 includes but is not limited to a random access memory (RAM), a read-only memory (ROM), an erasable programmable read only memory (EPROM), or a portable read-only memory (CD-ROM). The memory 802 is configured to store a related instruction or data, for example, a transport block. The transceiver 803 is configured to receive and send data.

The processor 801 may be one or more central processing units (CPU). When the processor 801 is one CPU, the CPU may be a single-core CPU, or may be a multi-core CPU.

The processor 801 in the apparatus 80 is configured to perform an information processing operation, or is configured to read program code stored in the memory 802, to perform an information processing operation. The information process operation specifically includes:

obtaining an encoding code rate of the transport block; and if a first code rate Rᵣₑₐₗ is greater than or equal to a second code rate Rₘᵢₙ, determining, based on a maximum code block length Kₘₐₓ of an LDPC, a quantity C of code blocks into which the transport block is to be segmented, where the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

In the foregoing operations, it is determined, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, a size of a buffer used by a receive end to store soft information of a code block is used, so that the quantity of code blocks obtained through calculation is more appropriate.

In an optional solution, if the first code rate Rᵣₑₐₗ is less than the second code rate Rₘᵢₙ, the processor is configured to determine, based on the first code rate Rᵣₑₐₗ and a maximum encoded length N_{CB} of a code block, the quantity C of code blocks into which the transport block is to be segmented, where

if the second code rate Rₘᵢₙ is the minimum code rate corresponding to the maximum code block length of the LDPC code, N_{CB} is a maximum encoded length Nₘₐₓ of the LDPC code; or if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

In another optional solution, the code rate limit of the maximum code block length of the LDPC code is Kₘₐₓ/N_{CB,limit}, and N_{CB,limit} is the size of the buffer used by the receive end to store the soft information of the code block.

In another optional solution, the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by the receive end to store soft information of the transport block.

In another optional solution, the processor is configured to determine, based on the maximum code block length Kₘₐₓ of the LDPC, the quantity of code blocks into which the transport block is to be segmented, where a value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the CRC bits of the transport block, and L_{CB,CRC} is a length of CRC bits of the code block.

In another optional solution, the processor is configured to determine, based on the first code rate and the maximum encoded length N_{CB} of the code block, the quantity of code blocks into which the transport block is to be segmented, where a value of the quantity C of code blocks into which the transport block is to be segmented satisfies:

C=└(TBS+L_{TB,CRC})/(└Rᵣₑₐₗ*N_{CB}┘−L_{CB,CRC})┘, or

C=┌(TBS+L_{TB,CRC})/(└Rᵣₑₐₗ*N_{CB}┘−L_{CB,CRC})┐, where

TBS is the length of the transport block, L_{TB,CRC} is the length of the CRC bits of the transport block, and L_{CB,CRC} is a length of CRC bits of the code block.

In another optional solution, if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or

if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, where

Th is a preset threshold.

In another optional solution, the preset threshold Th is equal to 0, or the preset threshold Th is less than or equal to a difference between the maximum code block length of the LDPC and a length of └Rᵣₑₐₗ*N_{CB}┘ and is greater than 0.

It should be noted that, for implementations of the operations, refer to the corresponding descriptions of the method embodiment shown in FIG. 4.

In the apparatus 80 shown in FIG. 8, it is determined, based on the relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, the size of the buffer used by the receive end to store the soft information of the code block is used, so that the quantity of code blocks obtained through calculation is more appropriate.

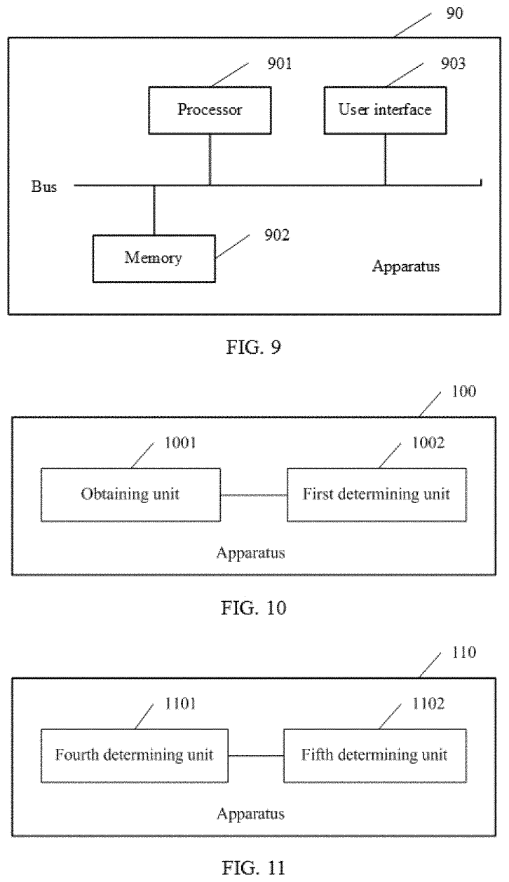

FIG. 9 shows an apparatus 90 according to an embodiment of the present invention. The apparatus 90 includes a processor 901, a memory 902, and a user interface 903. The processor 901, the memory 902, and the user interface 903 are interconnected through a bus.

The memory 902 includes but is not limited to a random access memory (RAM), a read-only memory (ROM), an erasable programmable read only memory (EPROM), or a portable read-only memory (CD-ROM). The memory 902 is configured to store a related instruction or data, for example, a transport block or program code. The transceiver 903 is configured to receive and send data.

The processor 901 may be one or more central processing units (CPU). When the processor 901 is one CPU, the CPU may be a single-core CPU, or may be a multi-core CPU.

The processor 901 in the apparatus 90 is configured to perform an information processing operation, or is configured to read the program code stored in the memory 902, to perform an information processing operation. The information process operation specifically includes:

determining whether a length obtained by encoding the transport block based on R_{min,K}_{ₘₐₓ} is greater than or equal to a smaller value in N_{IR} and G, where R_{min,K}_{ₘₐₓ} is a minimum code rate corresponding to a maximum code block length of an LDPC, N_{IR} is a size of a buffer used by a receive end to store soft information of the transport block, and G is a quantity of authorized bits used to transmit the transport block; and if the length obtained by encoding the transport block based on R_{min,K}_{ₘₐₓ} is greater than or equal to the smaller value in N_{IR} and G, determining, based on the maximum code block length Kₘₐₓ of the LDPC, a quantity of code blocks into which the transport block is to be segmented.

In the foregoing operations, an estimated length obtained by encoding the transport block is compared with a smaller value in a size of a buffer used by the receive end to store soft information of a code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on a length of the transport block and a minimum code rate of the LDPC. In this process, the size of the buffer used by the receive end to store the soft information of the code block is considered, so that the quantity of code blocks obtained through calculation is more appropriate.

In an optional solution, if the length obtained by encoding the transport block based on R_{min,K}_{ₘₐₓ} is less than the smaller value in N_{IR} and G, the processor is configured to determine, based on a length of the transport block and a minimum code rate of the LDPC, the quantity of code blocks into which the transport block is to be segmented.

In another optional solution, the processor is configured to determine, based on the length of the transport block and the minimum code rate of the LDPC, the quantity of code blocks into which the transport block is to be segmented, where a value of the quantity C of code blocks into which the transport block is to be segmented satisfies:

C=┌min((TBS+L_{TB,CRC})/R_{min,K}, G, N_{IR})/N_{CB}┐, or

C=└min((TBS+L_{TB,CRC})/R_{min,K}, G, N_{IR})/N_{CB}┘, where

TBS is the length of the transport block, L_{TB,CRC} is a length of cyclic redundancy check CRC bits of the transport block, R_{min,K} is the minimum code rate of the LDPC, and N_{CB} is a smaller value in a maximum encoded length Nₘₐₓ of the LDPC code and a size of a buffer used by the receive end to store soft information of the code block.

In another optional solution, the processor is configured to determine, based on the maximum code block length Kₘₐₓ of the LDPC, the quantity of code blocks into which the transport block is to be segmented, where the value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the cyclic redundancy check CRC bits of the transport block, and L_{CB,CRC} is a length of CRC bits of the code block.

It should be noted that, for implementations of the operations, refer to the corresponding descriptions of the method embodiment shown in FIG. 7.

In the apparatus 90 in FIG. 9, the estimated length obtained by encoding the transport block is compared with the smaller value in the size of the buffer used by the receive end to store the soft information of the code block and the quantity of bits that are authorized by the system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on the length of the transport block and the minimum code rate of the LDPC. In this process, the size of the buffer used by the receive end to store the soft information of the code block is considered, so that the quantity of code blocks obtained through calculation is more appropriate.

FIG. 10 is a schematic structural diagram of an apparatus 100 according to an embodiment of the present invention. The apparatus 100 may include an obtaining unit 1001 and a first determining unit 1002. Detailed descriptions of the units are as follows:

The obtaining unit 1001 is configured to obtain an encoding code rate of a transport block. If a first code rate Rᵣₑₐₗ is greater than or equal to a second code rate Rₘᵢₙ, the first determining unit 1002 is configured to determine, based on a maximum code block length Kₘₐₓ of an LDPC, a quantity C of code blocks into which the transport block is to be segmented. The first code rate Rᵣₑₐₗ is a largest one among the encoding code rate of the transport block, a code rate limit of the transport block, and a minimum code rate of the LDPC code. The second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

In the foregoing steps, it is determined, based on relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, a size of a buffer used by a receive end to store soft information of a code block is used, so that the quantity of code blocks obtained through calculation is more appropriate.

In an optional solution, if the first code rate Rᵣₑₐₗ is less than the second code rate Rₘᵢₙ, the first determining unit 1002 is configured to determine, based on the first code rate Rᵣₑₐₗ and a maximum encoded length N_{CB} of a code block, the quantity C of code blocks into which the transport block is to be segmented.

In another optional solution, the code rate limit of the maximum code block length of the LDPC code is Kₘₐₓ/N_{CB,limit}, and N_{CB,limit} is a size of a buffer used by a receive end to store soft information of the code block.

In another optional solution, the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by the receive end to store soft information of the transport block.

In another optional solution, that the first determining unit 1002 is configured to determine, based on a maximum code block length Kₘₐₓ of an LDPC, a quantity of code blocks into which the transport block is to be segmented includes: determining, based on the maximum code block length Kₘₐₓ of the LDPC, the quantity of code blocks into which the transport block is to be segmented, where a value of the quantity C of code blocks into which the transport block is to be segmented satisfies:

C=┌(TBS+L_{TB,CRC})/(Kₘₐₓ−L_{CB,CRC})┐, where

TBS is the length of the transport block, L_{TB,CRC} is the length of the CRC bits of the transport block, and L_{CB,CRC} is a length of CRC bits of the code block.

In another optional solution, the determining, based on the first code rate and a maximum encoded length N_{CB} of a code block, the quantity of code blocks into which the transport block is to be segmented includes: determining, based on the first code rate and the maximum encoded length N_{CB} of the code block, the quantity of code blocks into which the transport block is to be segmented, where a value of the quantity C of code blocks into which the transport block is to be segmented satisfies:

C=└(TBS+L_{TB,CRC})/(└Rᵣₑₐₗ*N_{CB}┘−L_{CB,CRC})┘, or

C=┌(TBS+L_{TB,CRC})/(└Rᵣₑₐₗ*N_{CB}┘−L_{CB,CRC})┐, where

TBS is the length of the transport block, L_{TB,CRC} is the length of the CRC bits of the transport block, and L_{CB,CRC} is a length of CRC bits of the code block.

In another optional solution, if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or

if a sum of the length of the transport block and the length of the CRC bits of the transport block is greater than the maximum code block length of the LDPC, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, where

Th is a preset threshold.

In another optional solution, the preset threshold Th is equal to 0, or the preset threshold Th is less than or equal to a difference between the maximum code block length of the LDPC and a length of └Rᵣₑₐₗ*N_{CB}┘ and is greater than 0. It should be noted that, for implementations of the units, refer to the corresponding descriptions of the method embodiment shown in FIG. 4.

In the apparatus 100 in FIG. 10, it is determined, based on the relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, the size of the buffer used by the receive end to store the soft information of the code block is used, so that the quantity of code blocks obtained through calculation is more appropriate.

FIG. 11 is a schematic structural diagram of an apparatus 110 according to an embodiment of the present invention. The apparatus 110 may include a fourth determining unit 1101 and a fifth determining unit 1102. Detailed descriptions of the units are as follows:

The fourth determining unit 1101 is configured to determine whether a length obtained by encoding a transport block based on R_{min,K}_{ₘₐₓ} is greater than or equal to a smaller value in N_{IR} and G, where R_{min,K}_{ₘₐₓ} is a minimum code rate corresponding to a maximum code block length of an LDPC, N_{IR} is a size of a buffer used by a receive end to store soft information of the transport block, and G is a quantity of authorized bits used to transmit the transport block. If the length obtained by encoding the transport block based on R_{min,K}_{ₘₐₓ} is greater than or equal to the smaller value in N_{IR} and G, the fifth determining unit 1102 is configured to determine, based on the maximum code block length Kₘₐₓ of the LDPC, a quantity of code blocks into which the transport block is to be segmented.

In the foregoing steps, an estimated length obtained by encoding the transport block is compared with a smaller value in a size of a buffer used by the receive end to store soft information of a code block and a quantity of bits that are authorized by a system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on a length of the transport block and a minimum code rate of the LDPC. In this process, the size of the buffer used by the receive end to store the soft information of the code block is considered, so that the quantity of code blocks obtained through calculation is more appropriate.

In an optional solution, if the length obtained by encoding the transport block based on R_{min,K}_{ₘₐₓ} is less than the smaller value in N_{IR} and G, the fifth determining unit 1102 is configured to determine, based on a length of the transport block and a minimum code rate of the LDPC, the quantity of code blocks into which the transport block is to be segmented.

In another optional solution, that the fifth determining unit 1102 is configured to determine, based on a length of the transport block and a minimum code rate of the LDPC, the quantity of code blocks into which the transport block is to be segmented includes: determining, based on the length of the transport block and the minimum code rate of the LDPC, the quantity of code blocks into which the transport block is to be segmented, where a value of the quantity C of code blocks into which the transport block is to be segmented satisfies:

C=┌min((TBS+L_{TB,CRC})/R_{min,K}, G, N_{IR})/N_{CB}┐, or

C=└min((TBS+L_{TB,CRC})/R_{min,K}, G, N_{IR})/N_{CB}┘, where

TBS is the length of the transport block, L_{TB,CRC} is a length of cyclic redundancy check CRC bits of the transport block, R_{min,K} is the minimum code rate of the LDPC, and N_{CB} is a smaller value in a maximum encoded length Nₘₐₓ of the LDPC code and a size of a buffer used by the receive end to store soft information of the code block.

In another optional solution, that the fifth determining unit 1102 is configured to determine, based on the maximum code block length Kₘₐₓ of the LDPC, a quantity of code blocks into which the transport block is to be segmented includes: determining, based on the maximum code block length Kₘₐₓ of the LDPC, the quantity of code blocks into which the transport block is to be segmented, where the value of the quantity C of code blocks into which the transport block is to be segmented satisfies:

C=┌(TBS+L_{TB,CRC})(Kₘₐₓ−L_{CB,CRC})┐, where

TBS is the length of the transport block, L_{TB,CRC} is the length of the cyclic redundancy check CRC bits of the transport block, and L_{CB,CRC} is a length of CRC bits of the code block.

It should be noted that, for implementations of the units, refer to the corresponding descriptions of the method embodiment shown in FIG. 7.

In the apparatus 110 in FIG. 11, the estimated length obtained by encoding the transport block is compared with the smaller value in the size of the buffer used by the receive end to store the soft information of the code block and the quantity of bits that are authorized by the system and that are used to transmit the transport block. If the estimated length obtained by encoding the transport block is larger, the quantity of code blocks into which the transport block is to be segmented is determined based on the maximum code block length Kₘₐₓ of the LDPC. If the estimated length obtained by encoding the transport block is smaller, the quantity of code blocks into which the transport block is to be segmented is determined based on the length of the transport block and the minimum code rate of the LDPC. In this process, the size of the buffer used by the receive end to store the soft information of the code block is considered, so that the quantity of code blocks obtained through calculation is more appropriate.

It may be understood that, the apparatuses (for example, the apparatus 80, the apparatus 90, the apparatus 100, and the apparatus 110) described in the foregoing embodiments may be one module or component. Therefore, the apparatus may be deployed in some devices. An embodiment of the present invention provides a device in which the apparatus is deployed. The device may determine a quantity of transport blocks based on the foregoing features of the apparatus.

In conclusion, in the embodiments of the present invention, it is determined, based on the relative values of the first code rate and the second code rate, how to calculate the quantity of code blocks into which the transport block is to be segmented, instead of directly calculating, based on the maximum code block length of the LDPC code, the quantity of code blocks into which the transport block is to be segmented. In the calculation process, the size of the buffer used by the receive end to store the soft information of the code block is used, so that the quantity of code blocks obtained through calculation is more appropriate.

A person of ordinary skill in the art can understand that all or some procedures in the methods in the foregoing embodiments may be implemented by a computer program instructing related hardware. The program may be stored in a computer readable storage medium. When the program is executed, the procedures of the foregoing method embodiments may be performed. The storage medium includes any medium that can store program code, such as a ROM, a random access memory RAM, a magnetic disk, or an optical disc.

What is claimed is:

1. An information processing method, comprising:
obtaining an encoding code rate of a transport block; and
if a first code rate Rᵣₑₐₗ is greater than or equal to a second code rate Rₘᵢₙ, determining, based on a maximum code block length Kₘₐₓ of an LDPC (low-density parity-check code) code, a quantity C of code blocks into which the transport block is to be segmented,
wherein the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

2. The method according to claim 1, comprising: if the first code rate Rᵣₑₐₗ is less than the second code rate Rₘᵢₙ, determining, based on the first code rate Rᵣₑₐₗ and a maximum encoded length N_{CB} of a code block, the quantity C of code blocks into which the transport block is to be segmented, wherein
if the second code rate Rₘᵢₙ is the minimum code rate corresponding to the maximum code block length of the LDPC code, N_{CB} is a maximum encoded length Nₘₐₓ of the LDPC code; or
if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

3. The method according to claim 1, wherein the code rate limit of the maximum code block length of the LDPC code is Kₘₐₓ/N_{CB,limit}, and N_{CB,limit} is a size of a buffer used by a receive end to store soft information of the code block.

4. The method according to claim 1, wherein the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by a receive end to store soft information of the transport block.

5. The method according to claim 1, wherein the determining, based on the maximum code block length Kₘₐₓ of the LDPC code, the quantity C of code blocks into which the transport block is to be segmented further comprises: determining, based on the maximum code block length Kₘₐₓ of the LDPC code, the quantity C of code blocks into which the transport block is to be segmented, wherein a value of the quantity C of code blocks into which the transport block is to be segmented satisfies:
C=┌(TBS+L_{TB,CRC})/(Kₘₐₓ−L_{CB,CRC})┐, wherein
TBS is a length of the transport block, L_{TB,CRC} is a length of the CRC bits of the transport block, and L_{CB,CRC} is a length of CRC bits of the code block.

6. The method according to claim 2, wherein the determining, based on the first code rate Rᵣₑₐₗ and the maximum encoded length N_{CB} of the code block, the quantity C of code blocks into which the transport block is to be segmented further comprises: determining, based on the first code rate Rᵣₑₐₗ and the maximum encoded length N_{CB} of the code block, the quantity of code blocks into which the transport block is to be segmented, wherein a value of the quantity C of code blocks into which the transport block is to be segmented satisfies:
C=└(TBS+L_{TB,CRC})/(└Rᵣₑₐₗ*N_{CB}┘−L_{CB,CRC})┘, or
C=┌(TBS+L_{TB,CRC})/(└Rᵣₑₐₗ*N_{CB}┘−L_{CB,CRC})┐, where
TBS is a length of the transport block, L_{TB,CRC} is a length of the CRC bits of the transport block, and L_{CB,CRC} is a length of CRC bits of the code block.

7. The method according to claim 6, wherein if a sum of the length of the transport block and the length of the CRC bits of the transport block is greater than the maximum code block length of the LDPC code, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or
if a sum of the length of the transport block and the length of the CRC bits of the transport block is greater than the maximum code block length of the LDPC code, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, wherein
Th is a preset threshold, and the preset threshold Th is equal to 0, or the preset threshold Th is less than or equal to a difference between the maximum code block length of the LDPC code and a length of └Rᵣₑₐₗ*N_{CB}┘ and is greater than 0.

8. An information processing apparatus, wherein the apparatus comprises a processor and a memory, the memory is configured to store a transport block, and the processor is configured to perform the following operations:
obtaining an encoding code rate of the transport block; and
if a first code rate Rᵣₑₐₗ is greater than or equal to a second code rate Rₘᵢₙ, determining, based on a maximum code block length Kₘₐₓ of an LDPC (low-density parity-check code) code, a quantity C of code blocks into which the transport block is to be segmented, wherein the first code rate Rᵣₑₐₗ is a largest one among the encoding code rate of the transport block, a code rate limit of the transport block, and a minimum code rate of the LDPC code, and the second code rate Rₘᵢₙ is a minimum code rate corresponding to the maximum code block length of the LDPC code, or a larger one between a minimum code rate corresponding to the maximum code block length of the LDPC code and a code rate limit of the maximum code block length of the LDPC code.

9. The apparatus according to claim 8, wherein if the first code rate Rᵣₑₐₗ is less than the second code rate Rₘᵢₙ, the processor is configured to determine, based on the first code rate Rᵣₑₐₗ and a maximum encoded length N_{CB} of a code block, the quantity C of code blocks into which the transport block is to be segmented, wherein
if the second code rate Rₘᵢₙ is the minimum code rate corresponding to the maximum code block length of the LDPC code, N_{CB} is a maximum encoded length Nₘₐₓ of the LDPC code; or
if the second code rate Rₘᵢₙ is the larger one between the minimum code rate corresponding to the maximum code block length of the LDPC code and the code rate limit of the maximum code block length of the LDPC code, N_{CB} is N_{CB,limit}, and N_{CB,limit} is a size of a buffer used by a receive end to store soft information of the code block.

10. The apparatus according to claim 8, wherein the code rate limit of the maximum code block length of the LDPC code is Kₘₐₓ/N_{CB,limit}, and N_{CB,limit} is a size of a buffer used by a receive end to store soft information of the code block.

11. The apparatus according to claim 8, wherein the code rate limit of the transport block is (TBS+L_{TB,CRC})/N_{IR}, TBS is a length of the transport block, L_{TB,CRC} is a length of cyclic redundancy check CRC bits of the transport block, and N_{IR} is a size of a buffer used by a receive end to store soft information of the transport block.

12. The apparatus according to claim 8, wherein the processor is configured to determine, based on the maximum code block length Kₘₐₓ of the LDPC code, the quantity C of code blocks into which the transport block is to be segmented, wherein a value of the quantity C of code blocks into which the transport block is to be segmented satisfies:
C=┌(TBS+L_{TB,CRC})/(Kₘₐₓ−L_{CB,CRC})┐, wherein
TBS is a length of the transport block, L_{TB,CRC} is a length of the CRC bits of the transport block, and L_{CB,CRC} is a length of CRC bits of the code block.

13. The apparatus according to claim 8, wherein the processor is configured to determine, based on the first code rate and the maximum encoded length N_{CB} of the code block, the quantity C of code blocks into which the transport block is to be segmented, wherein a value of the quantity C of code blocks into which the transport block is to be segmented satisfies:
C=└(TBS+L_{TB,CRC})/(└Rᵣₑₐₗ*N_{CB}┘−L_{CB,CRC})┘, or
C=┌(TBS+L_{TB,CRC})/(└Rᵣₑₐₗ*N_{CB}┘−L_{CB,CRC})┐, where
TBS is a length of the transport block, L_{TB,CRC} is a length of the CRC bits of the transport block, and L_{CB,CRC} is a length of CRC bits of the code block.

14. The apparatus according to claim 13, wherein
if a sum of the length of the transport block and the length of the CRC bits of the transport block is greater than the maximum code block length of the LDPC code, and the following condition (TBS+L_{TB,CRC})mod(└Rᵣₑₐₗ*N_{CB}┘−L_{CB,CRC})<Th is satisfied, the value of C satisfies C=└(TBS+L_{TB,CRC})/(└Rᵣₑₐₗ*N_{CB}┘−L_{CB,CRC})┘, or
if a sum of the length of the transport block and the length of the CRC bits of the transport block is greater than the maximum code block length of the LDPC code, and the following condition (TBS+L_{TB,CRC})mod(└Rᵣₑₐₗ*N_{CB}┘−L_{CB,CRC})≥Th is satisfied, the value of C satisfies C=┌(TBS+L_{TB,CRC})/(└Rᵣₑₐₗ*N_{CB}┘−L_{CB,CRC})┐, wherein
Th is a preset threshold, and the preset threshold Th is equal to 0, or the preset threshold Th is less than or equal to a difference between the maximum code block length of the LDPC code and a length of └Rᵣₑₐₗ*N_{CB}┘ and is greater than 0.

15. An information processing apparatus, wherein the apparatus comprises a processor and a memory, the memory is configured to store a transport block, and the processor is configured to perform the following operations:
determining whether a length obtained by encoding the transport block based on R_{min,K}_{ₘₐₓ} is greater than or equal to a smaller value in N_{IR} and G, wherein R_{min,K}_{ₘₐₓ} is a minimum code rate corresponding to a maximum code block length Kₘₐₓ of an LDPC (low-density parity-check code) code, N_{IR} is a size of a buffer used by a receive end to store soft information of the transport block, and G is a quantity of authorized bits used to transmit the transport block; and
if the length obtained by encoding the transport block based on R_{min,K}_{ₘₐₓ} is greater than or equal to the smaller value in N_{IR} and G, determining, based on the maximum code block length of the LDPC code, a quantity of code blocks into which the transport block is to be segmented.

16. The apparatus according to claim 15, wherein if the length obtained by encoding the transport block based on R_{min,K}_{ₘₐₓ} is less than the smaller value in N_{IR} and G, the processor is configured to determine, based on a length of the transport block and a minimum code rate of the LDPC code, the quantity of code blocks into which the transport block is to be segmented.

17. The apparatus according to claim 16, wherein the processor is configured to determine, based on the length of the transport block and the minimum code rate of the LDPC code, the quantity of code blocks into which the transport block is to be segmented, wherein a value of the quantity C of code blocks into which the transport block is to be segmented satisfies:
C=┌min((TBS+L_{TB,CRC})/R_{min,K}, G, N_{IR})/N_{CB}┐, or
C=└min((TBS+L_{TB,CRC})/R_{min,K}, G, N_{IR})/N_{CB}┘, where
TBS is the length of the transport block, L_{TB,CRC} is a length of cyclic redundancy check CRC bits of the transport block, R_{min,K} is the minimum code rate of the LDPC code, and N_{CB} is a smaller value in a maximum encoded length Nₘₐₓ of the LDPC code and the size of the buffer used by the receive end to store the soft information of the code block.

18. The apparatus according to claim 15, wherein the processor is configured to determine, based on the maximum code block length Kₘₐₓ of the LDPC code, the quantity of code blocks into which the transport block is to be segmented, wherein the value of the quantity C of code blocks into which the transport block is to be segmented satisfies:
C=┌(TBS+L_{TB,CRC})/(Kₘₐₓ−L_{CB,CRC})┐, wherein
TBS is a length of the transport block, L_{TB,CRC} is a length of cyclic redundancy check CRC bits of the transport block, and L_{CB,CRC} is a length of CRC bits of the code block.
